(19) United States
(12) Patent Application Publication
(10) Pub. No.: US 2015/0318265 A1
(43) Pub. Date: Nov. 5, 2015

(54) SEMICONDUCTOR DEVICE

(71) Applicant: PS4 LUXCO S.A.R.L., Luxembourg (LU)

(72) Inventor: Satoshi Isa, Tokyo (JP)

(21) Appl. No.: 14/650,293

(22) PCT Filed: Dec. 5, 2013
(86) PCT No.: PCT/JP2013/082713

§ 371 Date: Jun. 5, 2015

(30) Foreign Application Priority Data
Dec. 6, 2012 (JP) 2012-267212

(51) Int. Cl. H01L 25/065; H01L 23/00; H01L 23/498

(52) U.S. Cl. CPC H01L 25/0657; H01L 23/49838; H01L 24/02; H01L 2225/0651; H01L 2224/0237; H01L 2224/0235

(57) ABSTRACT

One semiconductor device has a wiring substrate, a first semiconductor chip, and a second semiconductor chip. Each semiconductor chip includes a first side and a third side which are opposed, a second side which is perpendicular to the first side, and a fourth side opposing the second side. A first electrode (CA electrode pad) parallel to the first side, and a second electrode (I/O electrode pad) arranged parallel to the second side near the second side, are provided on the first semiconductor chip. A third electrode (CA electrode pad) parallel to the first side, and a fourth electrode (I/O electrode pad) arranged parallel to the fourth side near the fourth side, are provided on the second semiconductor chip.

### TECHNICAL FIELD

The present invention relates to a semiconductor device.

### BACKGROUND ART

There has been an increased demand in recent years for the density of semiconductor devices mounted on circuit boards in compact electronic equipment such as mobile equipment to be increased to cope with reductions in the size of the equipment and increases in the level of functionality. To meet this demand, semiconductor devices in which a plurality of semiconductor chips are stacked on one wiring board have been devised. As one example thereof, patent literature article 1 (Japanese Patent Kokai 2011-249582) discloses a DDP (Dual Die Package) type semiconductor device in which two semiconductor chips are stacked on one wiring board.

Semiconductor chips in which electrode pad rows comprising a plurality of electrode pads (electrodes) are formed on one surface (the main surface) are used as the semiconductor chips mounted in many DDP-type semiconductor devices. The plurality of electrode pads are disposed in such a way as to form a row which is parallel to the pair of mutually opposing long edges of the rectangular semiconductor chip, and which passes through the central region of the semiconductor chip, and the plurality of electrode pads are each connected by wires or the like to a plurality of external electrodes formed on the surface (reverse surface) of the wiring board on the opposite side to the surface on which the semiconductor chips are mounted.

The row of electrode pads on the semiconductor chips discussed hereinabove is classified into two types of system. One type is a row of command and address (CA) system electrode pads which receive external signals. The other is a data (DQ) system signal and DQ system power supply/GND, in other words an Input/Output (I/O) system electrode pad row. Of these electrode pad rows, the I/O-system electrode pad (first electrode) row is located offset toward one end portion of the semiconductor chip. The CA-system electrode pad (second electrode) row is disposed toward the other end portion, on an extension of the I/O-system electrode pad row.

Of the external electrodes provided on the surface of the wiring board on the opposite side to the surface on which the semiconductor chips are mounted, the external electrodes connected to the I/O-system electrode pads are disposed respectively in two different regions of the rectangular wiring substrate, in other words in the vicinity of the pair of mutually opposing short edges. Such an arrangement is used in order to achieve an increase in the processing speed by improving the symmetry within the chip, and in order to facilitate wiring when the semiconductor device is mounted on a mounting board, said arrangement being defined in a standard.

In a DDP-type semiconductor device, if there is a significant difference in the lengths (wiring line lengths) of the conduction paths between the electrode pads on the semiconductor chips and the external electrodes, the terminal capacitances of the external electrodes having a long conduction path increase, and variability in the signal delay time (timing) increases, hindering increases in signal speed. Therefore in the semiconductor device in patent literature article 1, the I/O-system electrode pads on each semiconductor chip and the external electrodes are respectively disposed toward the same end portion (in the vicinity of one short edge) of the wiring board. By arranging the electrode pads and the external electrodes in this way, the lengths of the conduction paths from the I/O-system electrode pads on each semiconductor chip to the I/O external electrodes are made uniform. By this means, differences between the terminal capacitances of the I/O systems of each semiconductor chip can be reduced, and variability in the delay time (timing) can be reduced, and as a result the DDP-type semiconductor device can operate at a high speed.

### PATENT LITERATURE

Patent literature article 1: Japanese Patent Kokai 2011-249582

### SUMMARY OF THE INVENTION

### Problems to be Resolved by the Invention

In the semiconductor device disclosed in patent literature article 1, the CA-system wiring lines and the I/O-system wiring lines become partially intertwined at the boundary between the region in which the CA external electrodes are disposed and the region in which the I/O external electrodes are disposed, on the surface of the wiring board on the opposite side to the surface on which the semiconductor chips are mounted. This gives rise to the problem that noise asynchronously affects CA-system signals and I/O-system signals.

Meanwhile, bond fingers on the main surface of the wiring board are provided in the vicinity of the long edges of the wiring board, and the I/O-system electrode pads on the main surface of the semiconductor chip are disposed parallel to the long edges of the semiconductor chip. Wires are therefore arranged extending from the electrode pads toward the bond fingers close to the long edges. The lengths of the wires are made uniform in this way. However, because the I/O external electrodes on the reverse surface of the wiring board are disposed in the vicinity of the short edges of the wiring board and parallel to the short edges, the wiring lines from the bond fingers to the I/O external electrodes are disposed diagonally from the long edges of the wiring board toward the short edges. The lengths of the wiring lines from the bond fingers on the reverse surface of the wiring board to the I/O external electrodes are therefore not uniform. Further, because the region in which the wiring lines from the bond fingers to the I/O external electrodes and the region in which the CA external electrodes are disposed are close to one another, there is little space for the wiring lines to be routed circuitously, and the wiring lines cannot be routed circuitously. In other words, the wiring lines from the bond fingers on the reverse surface of the wiring board to the I/O external electrodes are long, and the lengths of the conduction paths from the I/O-system electrode pads to the I/O external electrodes cannot be made uniform.

Thus the lengths of the conduction paths between the electrode pads on each semiconductor chip and the external electrodes are long and are not readily made uniform, and therefore the terminal capacitances of the external electrodes having long conduction paths are large, and ultimately variability in the signal delay time (timing) increases. Increasing the signal speed is thus hindered.

Accordingly, the aim of the present invention is to resolve the abovementioned problems, and to provide a DDP-type semiconductor device in which CA-system wiring lines and I/O-system wiring lines do not readily become intertwined, and in which the lengths of the I/O-system conduction paths are made uniform, thereby making variability in the signal delay time small, and making high-speed operation possible.

### Means of Overcoming the Problems

In order to achieve the abovementioned aims, the present invention comprises a wiring board, a first semiconductor chip mounted on a main surface of the wiring board, and a second semiconductor chip stacked on the first semiconductor chip. The first semiconductor chip and the second semiconductor chip are each formed in the shape of a plate having a planar shape including a pair of mutually-opposing edges, namely a first edge and a third edge, a second edge perpendicular to the first edge, and a fourth edge opposing the second edge. There are provided on the main surface of the first semiconductor chip a plurality of first electrodes aligned in such a way as to form a row parallel to the first edge and passing through a plate-shaped central region, and a plurality of second electrodes aligned in the vicinity of the second edge in such a way as to form a row parallel to the second edge. There are provided on the main surface of the second semiconductor chip a plurality of third electrodes aligned in such a way as to form a row parallel to the first edge and passing through a plate-shaped central region, and a plurality of fourth electrodes aligned in the vicinity of the fourth edge in such a way as to form a row parallel to the fourth edge.

### Advantages of the Invention

By aligning the second electrodes on the main surface in the vicinity of the second edge of the first semiconductor chip and parallel to the second edge, the lengths of the conduction paths extending from the second electrodes to the external electrodes on the reverse surface of the wiring board can be made uniform. Similarly, by aligning the fourth electrodes on the main surface in the vicinity of the fourth edge of the second semiconductor chip and parallel to the fourth edge, the lengths of the conduction paths extending from the fourth electrodes to the external electrodes on the reverse surface of the wiring board can be made uniform. Further, the second electrodes and the fourth electrodes are formed in the vicinity of the second or the fourth edges, rather than on the centerline of the semiconductor chip, parallel to the first edge, and therefore the wiring lines connected to the second electrodes and the fourth electrodes extend in a different direction to the wiring lines connected to the first electrodes and the third electrodes. Thus the wiring lines connected to the second electrodes and the fourth electrodes do not readily become intertwined with the wiring lines connected to the first electrodes and the third electrodes.

The lengths of the conduction paths extending from the second electrodes and the fourth electrodes to the external electrodes are made uniform, and said conduction paths do not readily become intertwined with the conduction paths from the first electrodes and the third electrodes, and therefore in the semiconductor device there is little variability in the signal delay time (timing), and high-speed operation can be achieved.

### BRIEF EXPLANATION OF THE DRAWINGS

FIG. 1 is a cross-sectional view illustrating the configuration of a semiconductor device according to a first mode of embodiment of the present invention.

FIG. 2a is a plan view illustrating a state in which a first semiconductor chip is mounted on the main surface of a wiring board in the semiconductor device according to the first mode of embodiment.

FIG. 2b is a plan view illustrating a state in which a second semiconductor chip is mounted on the main surface of the first semiconductor chip in the first mode of embodiment.

FIG. 3 is a bottom view illustrating the configuration of the reverse surface of the wiring board in the semiconductor device according to the first mode of embodiment.

FIG. 4a is a cross-sectional view illustrating the assembly flow for the semiconductor device according to the first mode of embodiment.

FIG. 4b is a cross-sectional view illustrating the assembly flow for the semiconductor device according to the first mode of embodiment.

FIG. 4c is a cross-sectional view illustrating the assembly flow for the semiconductor device according to the first mode of embodiment.

FIG. 4d is a cross-sectional view illustrating the assembly flow for the semiconductor device according to the first mode of embodiment.

FIG. 4e is a cross-sectional view illustrating the assembly flow for the semiconductor device according to the first mode of embodiment.

FIG. 4f is a cross-sectional view illustrating the assembly flow for the semiconductor device according to the first mode of embodiment.

FIG. 5 is a cross-sectional view illustrating the configuration of a semiconductor device according to a second mode of embodiment of the present invention.

FIG. 6a is a plan view illustrating a state in which a first semiconductor chip is mounted on the main surface of a wiring board in the semiconductor device according to the second mode of embodiment.

FIG. 6b is a plan view illustrating a state in which a second semiconductor chip is mounted on the main surface of the first semiconductor chip in the second mode of embodiment.

FIG. 7 is a bottom view illustrating the configuration of the reverse surface of the wiring board in the semiconductor device according to the second mode of embodiment.

### MODES OF EMBODYING THE INVENTION

Modes of embodying the present invention will now be described with reference to the drawings.

### First Mode of Embodiment

FIG. 1 is a cross-sectional view illustrating the configuration of a semiconductor device according to a first mode of embodiment of the present invention.

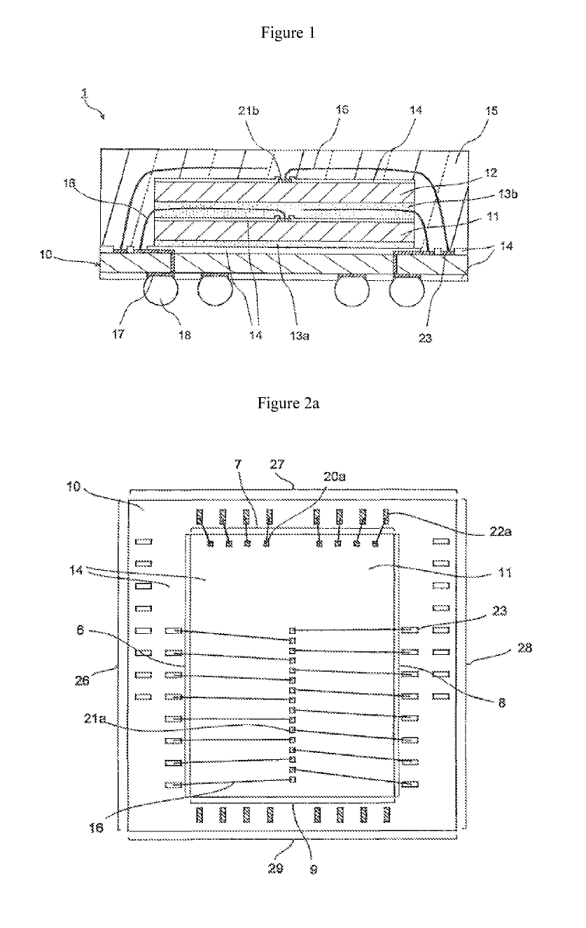

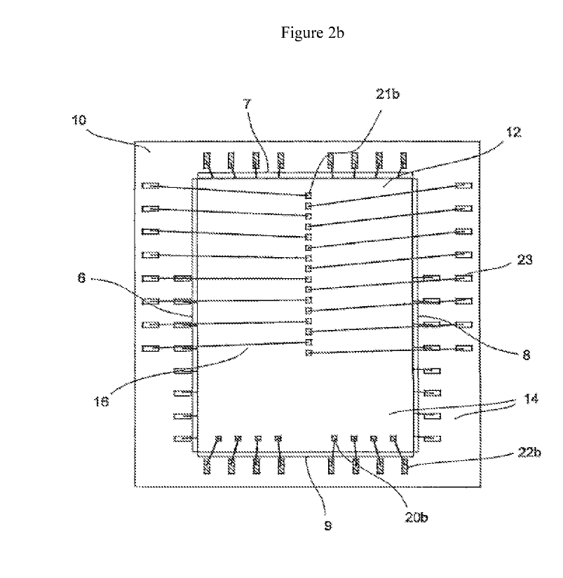

A semiconductor device 1 is a DDP (Dual Die Package) type semiconductor package comprising a plate-shaped first semiconductor chip 11 mounted on a wiring board 10 and a second semiconductor chip 12 stacked on the first semiconductor chip 11. The planar shape of the first semiconductor chip 11 is substantially a quadrilateral shape comprising first to fourth edges 6 to 9 (see FIG. 2a). I/O-system electrode pads 20 and CA-system electrode pads 21 are each provided on the main surfaces of the semiconductor chips 11 and 12. On the main surface of the wiring board 10, the electrode pads 20 and 21 are each wired to bond fingers 22 and 23 on the wiring board 10 using wires 16. On the reverse surface of the wiring substrate 10, through-vias connect the bond fingers 22 and 23 to external electrodes (external electrodes 24 for I/O-system pins and external electrodes 25 for CA-system pins) provided on the reverse surface of the wiring board 10. The wiring lines (wires 16) extending from the electrode pads 20 and 21, the bond fingers 22 and 23, and the through-vias extending from the bond fingers 22 and 23 form conduction paths connecting the electrode pads 20 and 21 to the external electrodes 24 and 25.

The wiring board 10 comprises a glass epoxy board (insulating board) having a thickness of 0.2 mm, for example. Prescribed wiring lines comprising a conductive material such as Cu are formed on the main surface (the surface on which the chips are mounted) and the reverse surface (the surface on which the electrodes are formed) of the insulating board. The main surface and the reverse surface of the insulating board are covered by an insulating film 14 (such as a solder resist). The wiring board 10 is in the shape of a plate having a substantially quadrilateral planar shape comprising fifth to eighth edges 26 to 29, and as illustrated in FIGS. 2a and 2b, the plurality of bond fingers 22 and 23 are disposed along the edges of the wiring board 10, in the vicinity of the edges, exposed through the insulating film 14. The plurality of bond fingers 22 and 23 are aligned in such a way as to surround a central region of the wiring board 10 on which the first semiconductor chip 11, discussed hereinafter, is to be mounted, and in such a way as to form rows parallel to the edges 6 to 9 of the mounted first semiconductor chip 11.

The wiring board 10 has a planar shape including a pair of mutually opposing edges, namely a fifth edge 26 and a seventh edge 28, a sixth edge 27 perpendicular to the fifth edge 26, and an eighth edge 29 opposing the sixth edge 27. In this mode of embodiment, the wiring board 10 has a substantially quadrilateral planar shape comprising the fifth to eighth edges 26 to 29, but it may be formed with a shape other than a quadrilateral.

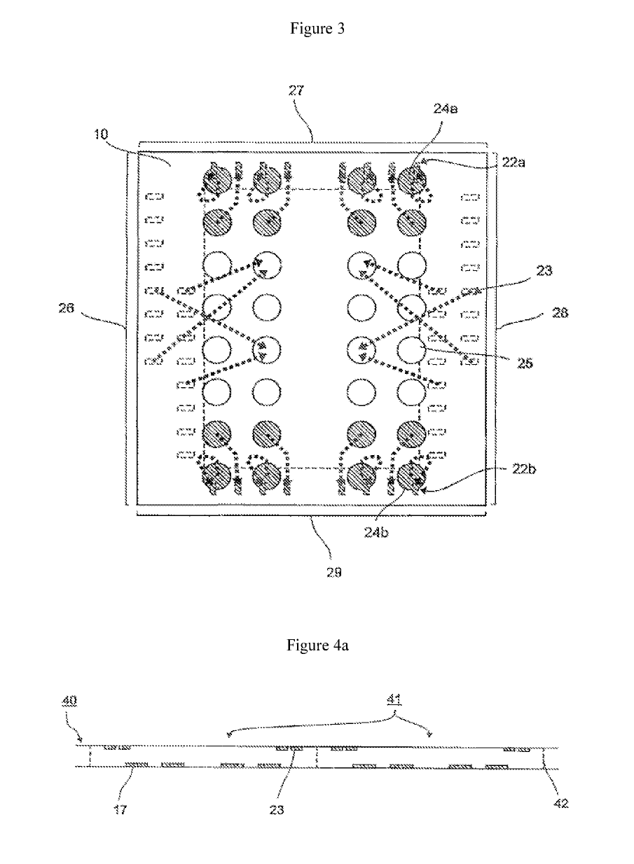

As illustrated in FIG. 3, a plurality of lands 17 are disposed in a lattice formation with a prescribed spacing on the reverse surface of the wiring board 10. The lands 17 are each electrically connected to corresponding bond fingers 22, 23 by means of wiring lines in the wiring board 10. Solder balls 18 are formed on the plurality of lands 17. The lands 17 and the solder balls 18 form the external electrodes (the external electrodes 24 for the I/O-system pins and the external electrodes 25 for the CA-system pins).

The plurality of lands 17 are connected to two types of electrode pads formed on the first semiconductor chip 11 and the second semiconductor chip 12, discussed hereinafter. The two types of electrode pads are data (DQ) system signal and DQ system power supply/GND, in other words Input/Output (I/O) system electrode pads 20 for data input and output, and command and address (CA) system electrode pads 21 which receive external signals. The plurality of lands 17 comprise external electrodes 24a for I/O-system pins (first external electrodes) connected to the electrode pads on the first semiconductor chip 11, external electrodes 24b for I/O-system pins (second external electrodes) connected to the electrode pads on the second semiconductor chip 12, and external electrodes 25 for CA-system pins.

As illustrated in FIG. 3, the external electrodes 24a for I/O-system pins, connected to the electrode pads on the first semiconductor chip 11, are disposed toward the sixth edge 27 of the wiring board 10, and when viewed in plan they are disposed in the vicinity of the second edge 7 of the first semiconductor chip 11, discussed hereinafter. The external electrodes 24b for I/O-system pins, connected to the electrode pads on the second semiconductor chip 12, are disposed toward the eighth edge 29 of the wiring board 10, and when viewed in plan they are disposed in the vicinity of the fourth edge 9 of the first semiconductor chip 11, discussed hereinafter. The external electrodes 25 for CA-system pins are disposed in the central region of the wiring board 10 in such a way as to sandwich the external electrodes 24a for I/O-system pins, connected to the electrode pads on the first semiconductor chip 11, and the external electrodes 24b for I/O-system pins, connected to the electrode pads on the second semiconductor chip 12.

The first semiconductor chip 11 is mounted on the main surface of the wiring board 10 with the interposition of a bonding agent such as an elastomer, or a DAF (Die Attached Film) 13a.

The first semiconductor chip 11 is in the shape of a plate having a substantially quadrilateral planar shape comprising first to fourth edges 6 to 9, and a memory circuit or the like (which is not shown in the drawings), and a plurality of electrode pads 20 and 21 are formed on its main surface. The first semiconductor chip 11 has a planar shape including a pair of mutually opposing edges, namely a first edge 6 and a third edge 8, a second edge 7 perpendicular to the first edge 6, and a fourth edge 9 opposing the second edge 7. An insulating film 14 (such as a passivation film) is also formed on the main surface of the first semiconductor chip 11. The plurality of electrode pads 20 and 21 are not covered by the insulating film 14, but are exposed. As discussed hereinabove, the plurality of electrode pads 20 and 21 include I/O-system electrode pads 20a (the plurality of second electrodes) and CA-system electrode pads 21a (the plurality of first electrodes). As illustrated in FIG. 2a, the plurality of CA-system electrode pads 21a are aligned in such a way as to form a row which is parallel to one of the long edges (the first edge 6) of the first semiconductor chip 11 and which passes through the central region of the first semiconductor chip 11. Meanwhile, the plurality of I/O-system electrode pads 20a are aligned in the vicinity of one of the short edges (the second edge 7) perpendicular to the first edge 6 of the first semiconductor chip 11, in such a way as to form a row which is parallel to the second edge 7.

The reverse surface of the first semiconductor chip 11 faces the wiring board 10, and is bonded to the wiring board 10 with the interposition of the bonding agent (DAF) 13a. In this mode of embodiment, the planar shape of the wiring board 10 is similar to the planar shape of the first semiconductor chip 11. Thus, in a state in which the wiring board 10 is bonded to the first semiconductor chip 11, the first edge 6 is located in the vicinity of the fifth edge 26 and parallel to the fifth edge 26, the second edge 7 is located in the vicinity of the sixth edge 27 and parallel to the sixth edge 27, and the fourth edge 9 is located in the vicinity of the eighth edge 29.

The I/O-system electrode pads 20a and the CA-system electrode pads 21a on the first semiconductor chip 11 are electrically connected to the plurality of bond fingers formed on the wiring board 10 by way of the electrically conductive wires 16 comprising Au, Cu or the like. The plurality of bond fingers comprise bond fingers 22a for I/O-system pins, connected to the electrode pads on the first semiconductor chip 11, bond fingers 22b for I/O-system pins, connected to the electrode pads on the second semiconductor chip 12, and the bond fingers 23 for CA-system pins. The bond fingers 22a for I/O-system pins, connected to the electrode pads on the first semiconductor chip 11, are aligned in a row in the vicinity of the second edge 7 of the first semiconductor chip 11 in such a way as to be parallel to the second edge 7. The bond fingers 22a for I/O-system pins, connected to the electrode pads on the first semiconductor chip 11, are in close proximity to the row of I/O-system electrode pads 20a on the first semiconductor chip 11 mounted on the wiring board 10. The bond fingers 22a for I/O-system pins, connected to the electrode pads on the first semiconductor chip 11, and the I/O-system electrode pads 20a on the first semiconductor chip 11 are electrically connected by way of the wires 16. The bond fingers 22b for I/O-system pins, connected to the electrode pads on the second semiconductor chip 12, are aligned in a row in the vicinity of the fourth edge 9 of the second semiconductor chip 12 in such a way as to be parallel to the fourth edge 9. The bond fingers 23 for CA-system pins are aligned in the vicinity of the first edges 6 and the third edges 8 of the first and second semiconductor chips 11 and 12, in such a way as to be parallel to the first edges 6, and are electrically connected to the CA-system electrode pads 21a on the first semiconductor chip 12 by way of the wires 16.

The external electrodes 24a for I/O-system pins, connected to the electrode pads on the first semiconductor chip 11, and the bond fingers 22a for I/O-system pins, connected to the electrode pads on the first semiconductor chip, are electrically connected by way of through-vias and wires (wiring lines), which are not shown in the drawings. The external electrodes 25 for CA-system pins and the bond fingers 23 for CA-system pins, connected to the electrode pads on the first semiconductor chip 11, are electrically connected by way of through-vias and wires (wiring lines), which are not shown in the drawings. The through-vias and the wires (wiring lines) joining the external electrodes 24a for I/O-system pins, connected to the electrode pads on the first semiconductor chip 11, and the bond fingers 22a for I/O-system pins, connected to the electrode pads on the first semiconductor chip, are formed in such a way that their respective lengths are equal. The respective lengths of the conduction paths from the I/O-system electrode pads 20a on the first semiconductor chip 11 to the external electrodes 24a for I/O-system pins are thus made uniform.

The second semiconductor chip 12 is stacked on the main surface of the first semiconductor chip 11 with the interposition of a bonding member such as an FOW (Film On Wire). The first semiconductor chip 11 and the second semiconductor chip 12 are bonded in such a way that the wires 16 disposed on the main surface of the first semiconductor chip 11 are embedded in the bonding member (FOW) 13b.

The second semiconductor chip 12 is in the shape of a plate having a substantially quadrilateral planar shape comprising first to fourth edges 6 to 9. In this mode of embodiment, the planar shape of the wiring board 10 is similar to the planar shape of the first semiconductor chip 11. The first semiconductor chip 11 and the second semiconductor chip 12 have the same planar shape. A memory circuit or the like (which is not shown in the drawings), I/O-system electrode pads 20b (the plurality of third electrodes) and CA-system electrode pads 21b (the plurality of fourth electrodes) are formed on the main surface of the second semiconductor chip 12. The second semiconductor chip 12 has a planar shape including a pair of mutually opposing edges, namely a first edge 6 and a third edge 8, a second edge 7 perpendicular to the first edge 6, and a fourth edge 9 opposing the second edge 7. As illustrated in FIG. 2b, the plurality of CA-system electrode pads 21b are aligned in such a way as to form a row which is parallel to one of the long edges (the first edge 6) of the second semiconductor chip 12 and which passes through the central region of the second semiconductor chip 12. The plurality of I/O-system electrode pads 20b are aligned in a row in the vicinity of one of the short edges (the fourth edge 9) substantially perpendicular to the first edge 6 of the second semiconductor chip 12, in such a way as to be parallel to the fourth edge 9. In other words, the I/O-system electrode pads 20a on the first semiconductor chip 11 and the I/O-system electrode pads 20b on the second semiconductor chip 12 are disposed respectively at mutually opposing end portions of the second semiconductor chips 11 and 12 as viewed in plan. The reverse surface of the second semiconductor chip 12 faces the first semiconductor chip 11, and is bonded to the first semiconductor chip 11 with the interposition of the bonding agent (FOW) 13b in such a way as to coincide with the first semiconductor chip 11 mounted on the wiring board 10.

The I/O-system electrode pads 20b and the CA-system electrode pads 21b on the second semiconductor chip 12 are electrically connected to the plurality of bond fingers 22 and 23 formed on the wiring board 10 by way of the electrically conductive wires 16 (wiring lines) comprising Au, Cu or the like. The bond fingers 22b for I/O-system pins, connected to the electrode pads on the second semiconductor chip 12, are aligned in a row in the vicinity of the eighth edge 29 of the wiring board 10, in such a way as to be parallel to the eighth edge 29, and are in close proximity to the I/O-system electrode pads 20b on the second semiconductor chip 12. The bond fingers 22b for I/O-system pins, connected to the electrode pads on the second semiconductor chip 12, and the I/O-system electrode pads 20b on the second semiconductor chip 12 are electrically connected by way of the wires 16. The CA-system electrode pads 21b on the second semiconductor chip 12 are electrically connected by way of the wires 16 to the bond fingers 23 for CA-system pins, aligned parallel to the fifth edge 26 and the seventh edge 28 of the wiring board 10.

The external electrodes 24b for I/O-system pins, connected to the electrode pads on the second semiconductor chip 12, and the bond fingers 22b for I/O-system pins, connected to the electrode pads on the second semiconductor chip 12, are electrically connected by way of through-vias and wires (wiring lines), which are not shown in the drawings. Further, the external electrodes 25 for CA-system pins and the bond fingers 23 for CA-system pins, connected to the electrode pads on the second semiconductor chip 12, are electrically connected by way of through-vias and wires (wiring lines), which are not shown in the drawings. The through-vias and the wires (wiring lines) joining the external electrodes 24b for I/O-system pins, connected to the electrode pads on the second semiconductor chip 12, and the bond fingers 22b for I/O-system pins, connected to the electrode pads on the second semiconductor chip, are formed in such a way that their respective lengths are equal. The respective lengths of the conduction paths from the I/O-system electrode pads 20b on the second semiconductor chip 12 to the external electrodes 24b for I/O-system pins are thus made uniform.

A sealing resin 15 is formed on the main surface side of the wiring board 10 on which the first semiconductor chip 11 and the second semiconductor chip 12 have been stacked, in such a way as to cover the first semiconductor chip 11, the second semiconductor chip 12 and the wires 15 on the main surface of the second semiconductor chip 12. The sealing resin is formed from a thermosetting resin such as an epoxy resin, and the sealing resin 15 protects the first semiconductor chip 11, the second semiconductor chip 12 and the wires 16 on the main surface of the second semiconductor chip 12.

As discussed hereinabove, the two rows of I/O-system electrode pads 20 are formed respectively in the vicinity of the second edge 7 of the first semiconductor chip 11 and in the vicinity of the fourth edge 9 of the second semiconductor chip 12, and are in close proximity to the bond fingers 22 for I/O-system pins, on the wiring board 10. The bond fingers 22 for I/O-system pins are each electrically connected on the reverse surface of the wiring board 10 by an equal length to the external electrodes for I/O-system pins. Therefore, by the I/O-system electrode pads 20 and the bond fingers 22 for I/O-system pins being brought in close proximity to one another, the lengths of the wires 16 connected thereto are reduced, and are at the same time made uniform, and therefore the lengths of the conduction paths between the I/O-system electrode pads 20 and the external electrodes for I/O-system pins become uniform. By making the lengths of the conduction paths between the I/O-system electrode pads 20 and the external electrodes for I/O-system pins equal, differences in the terminal capacitances of the I/O systems for each semiconductor chip, and variability in the delay time (timing) of the I/O-system wiring lines, are reduced, and the DDP-type semiconductor device 1 is able to operate at high speed.

Further, the external electrodes for I/O-system pins, electrically connected to the I/O-system electrode pads 20, are provided on the reverse surface of the wiring board 10, in the vicinity of the sixth edge 27 and the eighth edge 29 of the wiring board 10, and parallel to the sixth edge 27 and the eighth edge 29. Symmetry within the memory chip thus improves, and an increase in the speed of the device can be achieved. Further, wiring can be effected on a mounting board such as a memory module board.

In addition, the CA-system electrode pads 21 are formed as a row parallel to the first edge 6 and passing though the central region of the semiconductor chip, and therefore the wiring lines from the CA-system electrode pads 21 to the bond fingers 23 for CA-system pins extend toward the fifth edge 26 and the seventh edge 28 of the wiring board 10. Therefore the I/O-system wiring lines extending toward the sixth edge 27 and the eighth edge 29 of the wiring board 10 do not become intertwined on the main surface of the wiring board 10 with the CA-system wiring lines. Further, on the reverse surface of the wiring board 10 also, the I/O-system wiring lines extend from the sixth edge 27 and the eighth edge 29 sides of the wiring board 10 toward the external electrodes for I/O-system pins, and the CA-system wiring lines extend from the fifth edge 26 and the seventh edge 28 sides toward the external electrodes for CA-system pins. The respective wiring lines therefore do not become intertwined. Because the I/O-system wiring lines and the CA-system wiring lines do not become intertwined on the wiring board 10, the problem that their respective actions are affected asynchronously by noise is suppressed. Further, by disposing the I/O-system wiring lines remote from the CA-system wiring lines, space is generated around the I/O-system wiring lines. The arrangement of the I/O-system wiring line conduction paths can therefore be readily adjusted, and the lengths can be made uniform, thereby making it more simple for the semiconductor device 1 to operate at high speed.

Further, when the second semiconductor chip 12 is stacked, the wires 16 arranged on the main surface of the first semiconductor chip 11 are fixed by being embedded in the bonding agent (FOW) 13b, thereby reducing the occurrence of wire short circuiting and wire sweep when the sealing resin 15 is formed Further, reducing the lengths of the wires 16 connecting the I/O-system electrode pads 20 to the bond fingers for I/O-system pins suppresses the occurrence of wire short circuiting and wire sweep when the sealing resin 15 is formed. The reliability of the semiconductor device 1 thus improves.

A method of manufacturing the semiconductor device 1 according to the present invention will now be described.

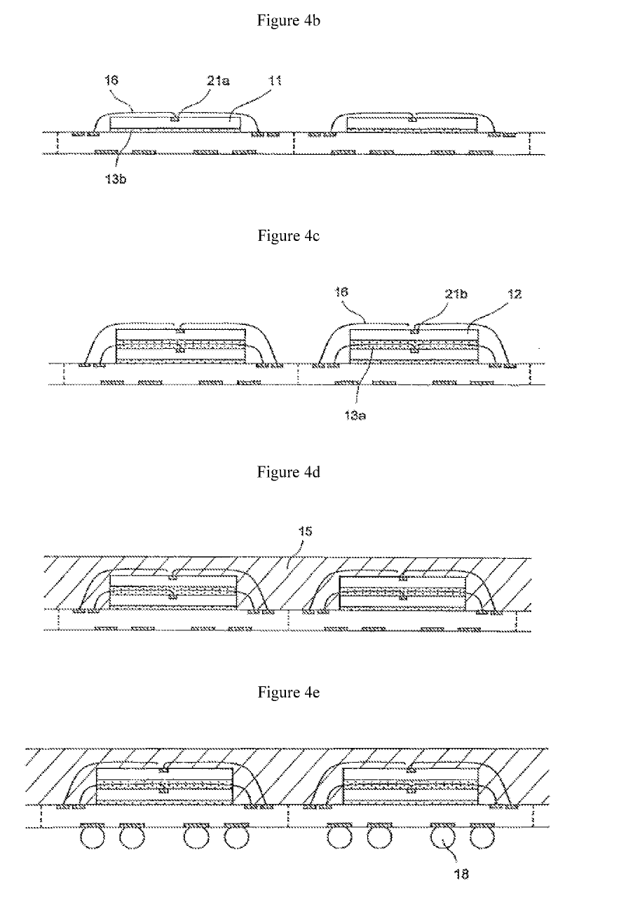

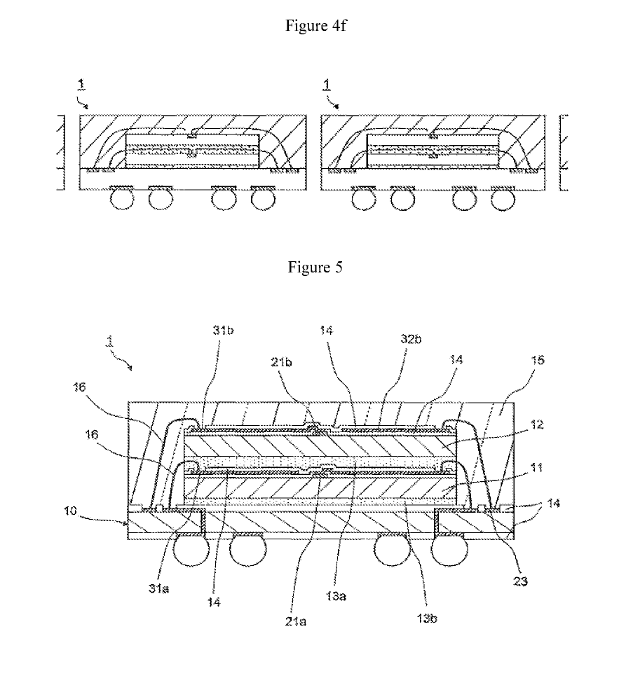

FIGS. 4a to 4f are cross-sectional views illustrating the steps in the method of manufacturing the semiconductor device 1 in this mode of embodiment.

First, a wiring mother board 40 on which a plurality of product-forming regions 41 are disposed in a matrix formation is prepared. The wiring mother board 40 is processed using an MAP (Mold Array Process), and is finally diced to form a plurality of wiring boards 10. As illustrated in FIG. 4a, the product-forming regions 41 are regions corresponding to the individual wiring boards 10 after dicing, a plurality of bond fingers are formed on the main surface, and a plurality of lands are formed on the reverse surface, and the product-forming regions 41 are demarcated by dicing lines 42 provided on the wiring mother board 40. Frame portions, which are not shown in the drawings, are provided around the product-forming regions 41 disposed in a matrix formation, and positioning holes, which are not shown in the drawings, for conveying and positioning the wiring mother board 40, are provided with a prescribed spacing in the frame portions.

Next, as illustrated in FIG. 4b, the first semiconductor chips 11 are bonded securely to the product-forming regions 41 of the wiring mother board 40 with the interposition of the bonding members (DAF) 13b. The bonding member may for example be a tape member comprising bonding layers on both surfaces of an insulating substrate, or an adhesive member such as an elastomer. At this time, the first semiconductor chips 11 are disposed in such a way that the reverse surface on which the electrode pads are not formed faces the wiring mother board 40. Then the electrode pads formed on the main surface of the first semiconductor chips 11 and the bond fingers formed on the product-forming regions 41 of the wiring mother board 40 are electrically connected using the electrically conductive wires 16 comprising Au or the like. Here, first one end portion of the wire 16 is melted using a wire bonding device, which is not shown in the drawings, to form a ball at the distal end of the wire 16. The wire 16 and the electrode pad are connected by ultrasonic thermo-compression bonding the end portion, at which the ball has been formed, onto the electrode pad of the first semiconductor chip 11. The other end portion of the wire 16 is then ultrasonic thermo-compression bonded onto the corresponding bond finger, while the wire 16 is made to describe a prescribed shape. The electrode pads and the bond fingers are thus electrically connected. It should be noted that the connections between the electrode pads and the bond fingers using the wires 16 may be performed by reverse bonding in order to lower the wire loops.

Next, as illustrated in FIG. 4c, the second semiconductor chips 12 are mounted on the main surfaces of the first semiconductor chips 11 with the interposition of the bonding members (FOW) 13a, thereby stacking the first semiconductor chips 11 and the second semiconductor chips 12 on one another. Then, using the same method as for the first semiconductor chip 11, the electrode pads on the second semiconductor chips 12 and the bond fingers formed on the product-forming regions 41 of the wiring mother board 40 are electrically connected using the electrically conductive wires 16 comprising Au or the like. The wires 16 may be formed by reverse bonding.

As illustrated in FIG. 4d, after the semiconductor chips 11 and 12 have been mounted on the wiring mother board 40, the sealing resin 15 comprising an insulating resin is formed covering collectively the side of the wiring mother board 40 on which the semiconductor chips have been mounted (the main surface side). In this case, the wiring mother board 40 is first, for example, accommodated and clamped inside a molding die comprising an upper die and a lower die of a transfer molding device, which is not shown in the drawings. A thermosetting epoxy resin is then introduced under pressure from a gate, which is not shown in the drawings, into the cavity formed by the upper die and the lower die, filling the cavity with the resin, after which resin is thermally cured to form the sealing resin 15.

As illustrated in FIG. 4e, after the sealing resin 15 has been formed, the electrically conductive solder balls 18 comprising solder or the like are mounted on the plurality of lands 17 that are disposed in a lattice formation on the reverse surface of the wiring mother board 40. A ball mounting tool, which is not shown in the drawings, in which a plurality of suction-attachment holes are formed corresponding to the arrangement of the lands 17 on the wiring mother board 40, is used in the ball mounting process. The solder balls 18 are retained by the suction holes, and flux is transferred to the retained solder balls 18, after which the ball mounting tool mounts the solder balls 18 all together onto the lands 17 of the wiring mother board 40. After the solder balls 18 have been mounted, reflow is performed at a prescribed temperature to secure the solder balls 18 to the lands 17 of the wiring mother board 40. The wiring mother board 40, in which the solder balls 18 have been mounted in this way onto all the lands 17, is passed to a board dicing process.

Finally, as illustrated in FIG. 4f, the wiring mother board 40 is cut along dicing lines 42, dividing it into individual product-forming regions 41. In this board dicing process, dicing tape, which is not shown in the drawings, is first bonded to the sealing resin 15 of the wiring mother board 40, and the wiring mother board 40 is supported by the dicing tape. A dicing blade, which is not shown in the drawings, is then used to cut the wiring mother board 40 lengthwise and crosswise along the dicing lines 42 into individual pieces, thereby completing the semiconductor device 1.

The DDP-type semiconductor device 1 in which asynchronous noise does not readily affect the respective actions of the I/O system and the CA system, which is capable of high-speed operation, and which has a high reliability, is manufactured in this way.

### Second Mode of Embodiment

FIG. 5 is a cross-sectional view illustrating the configuration of a semiconductor device according to a second mode of embodiment of the present invention.

A DDP-type semiconductor device 1 comprises a first semiconductor chip 11 mounted on a wiring board 10, which has a substantially quadrilateral plate shape, and a second semiconductor chip 12 stacked on the first semiconductor chip 11. The configuration of the wiring board 10 is the same as in the first mode of embodiment and a description thereof is therefore omitted.

The first semiconductor chip 11 is mounted on the main surface of the wiring board 10 with the interposition of a bonding member (DAF) 13b.

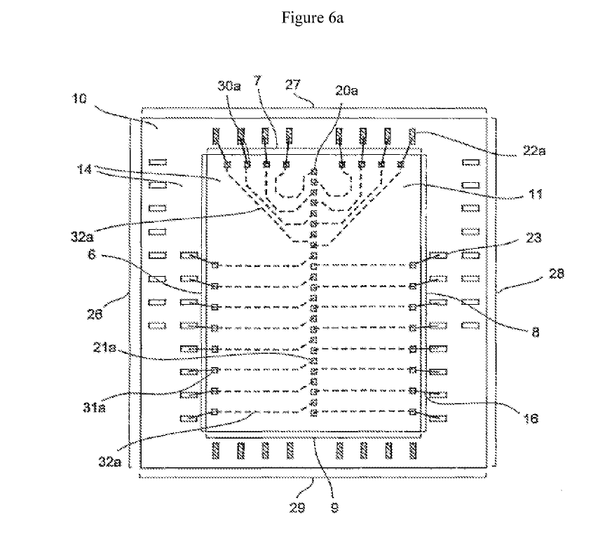

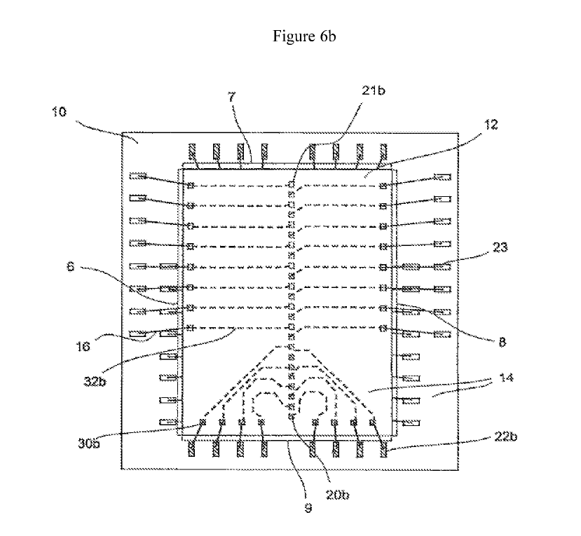

The first semiconductor chip 11 is in the shape of a substantially quadrilateral plate comprising first to fourth edges 6 to 9, and a memory circuit or the like (which is not shown in the drawings), and a plurality of electrode pads 20 and 21 are formed on its main surface. The first semiconductor chip 11 has a planar shape including a pair of mutually opposing edges, namely a first edge 6 and a third edge 8, a second edge 7 perpendicular to the first edge 6, and a fourth edge 9 opposing the second edge 7. An insulating film 14 is formed on the main surface of the first semiconductor chip 11, and the plurality of electrode pads 20 and 21 are not covered by the insulating film 14, but are exposed. The plurality of electrode pads 20 and 21 include I/O-system electrode pads 20a (a plurality of fifth electrodes) and CA-system electrode pads 21a (a plurality of first electrodes). As illustrated in FIG. 6a, the CA-system electrode pads 21a are aligned in such a way as to form a row which is parallel to one of the long edges (the first edge 6) of the first semiconductor chip 11 and which passes through the central region of the first semiconductor chip 11. The I/O-system electrode pads 20a are aligned in such a way as to form a row parallel to the first edge 6 and passing through the central region of the first semiconductor chip 11, and in such a way as to be located on an extension of the row of CA-system electrode pads 21a. The I/O-system electrode pads 20a are aligned on the main surface of the first semiconductor chip 11, offset toward the end portion that includes the second edge 7, and the CA-system electrode pads 21a are aligned offset toward the end portion that includes the fourth edge 9.

As illustrated in FIG. 5, redistribution wiring layers (RDL (Redistribution layer) wiring lines) 32a comprising Cu or the like are formed on the main surface of the first semiconductor chip 11. As illustrated in FIG. 6a, the CA-system electrode pads 21a are redistributed toward the first edge 6 and the third edge 8 of the first semiconductor chip 11 by means of the redistribution wiring layers 32a, and are electrically connected to CA-system connection pads 31a formed in the vicinity of the first edge 6 and the third edge 8. The I/O-system electrode pads 20a are redistributed (first redistribution wiring lines) toward the second edge 7 by means of the redistribution wiring layers 32a, and are each electrically connected to I/O-system connection pads 30a (a plurality of second electrodes) formed in the vicinity of the second edge 7. The redistribution wiring lines from the I/O-system electrode pads 20a to the I/O-system connection pads 30a are wired in a circuitous manner in such a way that the respective lengths of the redistribution wiring lines are equal. An insulating film 14 is formed on the redistribution wiring layers 32a, and the connection pads are not covered by the insulating film 14 but are exposed. The CA-system connection pads 31a are electrically connected to bond fingers 23 for CA-system pins, on the wiring board 10, by way of electrically conductive wires 16 comprising Au, Cu or the like. The I/O-system connection pads 30a and the bond fingers 22a for I/O-system pins, on the wiring board 10, for connecting to the electrode pads on the first semiconductor chip, are electrically connected by way of the wires 16.

The reverse surface of the first semiconductor chip 11 faces the wiring board 10, and is bonded to the wiring board 10 with the interposition of the bonding agent (DAF) 13a. In a state in which the wiring board 10 is bonded to the first semiconductor chip 11, the first edge 6 is disposed in the vicinity of the fifth edge 26 and parallel to the fifth edge 26, the second edge 7 is disposed in the vicinity of the sixth edge 27 and parallel to the sixth edge 27, and the fourth edge 9 is disposed in the vicinity of the eighth edge 29.

The second semiconductor chip 12 is stacked on the main surface of the first semiconductor chip 11 with the interposition of a bonding member (FOW) 13b. The first semiconductor chip 11 and the second semiconductor chip 12 are bonded in such a way that the wires 16 disposed on the main surface of the first semiconductor chip 11 are embedded in the bonding agent (FOW) 13b.

The second semiconductor chip 12 is in the shape of a substantially quadrilateral plate comprising first to fourth edges 6 to 9, and a memory circuit or the like (which is not shown in the drawings), and a plurality of electrode pads 20 and 21 are formed on its main surface. The second semiconductor chip 12 has a planar shape including a pair of mutually opposing edges, namely a first edge 6 and a third edge 8, a second edge 7 perpendicular to the first edge 6, and a fourth edge 9 opposing the second edge 7. An insulating film 14 is formed on the main surface of the second semiconductor chip 12, and the plurality of electrode pads 20 and 21 are not covered by the insulating film 14, but are exposed. The plurality of electrode pads 20 and 21 include I/O-system electrode pads 20b (a plurality of sixth electrodes) and CA-system electrode pads 21b (a plurality of second electrodes). As illustrated in FIG. 6b, the CA-system electrode pads 21b are aligned in such a way as to form a row which is parallel to one of the long edges (the first edge 6) of the second semiconductor chip 12 and which passes through the central region of the second semiconductor chip 12. The I/O-system electrode pads 20b are aligned in such a way as to form a row parallel to the first edge 6 and passing through the central region of the second semiconductor chip 12, and in such a way as to be located on an extension of the row of CA-system electrode pads 21b. The I/O-system electrode pads 20b are aligned on the main surface of the second semiconductor chip 11, offset toward the end portion that includes the fourth edge 9, and the CA-system electrode pads 21b are aligned offset toward the end portion that includes the second edge 7.

As illustrated in FIG. 5, redistribution wiring layers (RDL wiring lines) 32b comprising Cu or the like are formed on the main surface of the second semiconductor chip 12. The CA-system electrode pads 21b are electrically connected to CA-system connection pads 31b formed in the vicinity of the first edge 6 and the third edge 8 of the second semiconductor chip 12, in the same way as the first semiconductor chip 11. The I/O-system electrode pads 20b are redistributed (second redistribution wiring lines) toward the fourth edge 9 by means of the redistribution wiring layers 32b, and are each electrically connected to I/O-system connection pads 30b (a plurality of sixth electrodes) formed in the vicinity of the fourth edge 9. The redistribution wiring lines from the I/O-system electrode pads 20b to the I/O-system connection pads 30b are wired in such a way that the respective lengths of the redistribution wiring lines are equal. An insulating film 14 is formed on the redistribution wiring layers 32b, and the connection pads are not covered by the insulating film 14 but are exposed.

In the same way as with the first semiconductor chip 11, the I/O-system connection pads 30b and the CA-system connection pads 31b are each electrically connected to corresponding bond fingers by way of the wires 16.

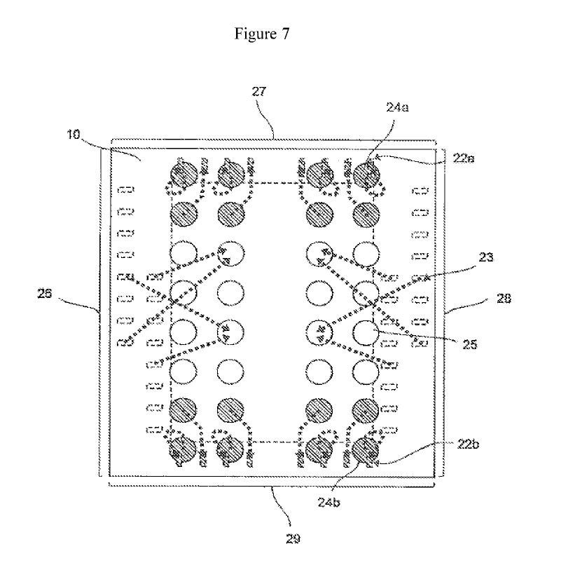

The configuration of the connections between the bond fingers and the lands on the reverse surface of the wiring board 10 illustrated in FIG. 7, and aspects of the configuration other than those described hereinabove, are the same as in the first mode of embodiment, and descriptions are therefore omitted.

By adopting a configuration such as that discussed hereinabove, the lengths of the conduction paths between the electrode pads and the external electrodes are made equal, in the same way as in the first mode of embodiment, and thus differences in the terminal capacitances of the I/O systems for each semiconductor chip, and variability in the delay time (timing) of the I/O-system wiring lines, are reduced. In addition, symmetry within the memory chip is improved, and the I/O-system wiring line conduction paths can be readily adjusted, thereby making it possible for the DDP-type semiconductor device to operate at high speed. Further, because the I/O-system wiring lines and the CA-system wiring lines do not become intertwined, the problem that their respective actions are affected asynchronously by noise is suppressed. Moreover, the occurrence of wire short circuiting and wire sweep when the sealing resin 15 is formed is reduced, improving the reliability of the semiconductor device.

In addition to such advantages obtained with the first mode of embodiment, because the I/O-system electrode pads are redistributed to the I/O-system connection pads in a circuitous manner rather than in a straight line, the lengths of the redistribution wiring lines between the electrode pads in the central region of the semiconductor chip and the connection pads are made uniform. Concomitant with this, the lengths of the conduction paths from the electrode pads on the semiconductor chips to the external electrodes on the wiring board become equal. If, for sake of argument, there is a difference in the lengths of wiring lines on the wiring board 10, then by adjusting the lengths of the redistribution wiring layers on the semiconductor chips it is possible for the lengths of the conduction paths from the electrode pads on the semiconductor chips to the external electrodes on the wiring board to be made equal. It should be noted that in the semiconductor device according to this mode of embodiment, the redistribution wiring layers are formed on the semiconductor chips, the CA-system electrode pads are redistributed toward the fifth edge 26 and the seventh edge 28 of the wiring board, and the I/O-system electrode pads are redistributed toward the sixth edge 27 and the eighth edge 29 of the wiring board. Alternatively, a configuration may be adopted in which sub-wiring boards are mounted on the semiconductor chips, and wiring lines are redistributed. Further, the electrode pads provided in the central region of the main surface of the semiconductor chip, described hereinabove, are aligned in one row, but the electrode pads may be aligned in two rows, or in three or more rows.

Further, in the first and second modes of embodiment described hereinabove the wiring board has a similar planar shape to the first and second semiconductor chips, but the configuration is not limited to such a configuration.

In each mode of embodiment the configuration is such that all the I/O-system electrode pads are disposed toward the short sides, but if they cannot be disposed toward the short sides, as a consequence of the chip size, the configuration may be such that some of the I/O-system electrode pads are disposed in the same direction as the row of CA-system electrode pads.

Specific configurations of the semiconductor device according to the present invention have been described hereinabove with reference to exemplary embodiments, but the present invention is not restricted to the exemplary embodiments described hereinabove, and it goes without saying that various modifications to the modes of embodiment described hereinabove are possible without deviating from the gist of the invention.

### EXPLANATION OF THE REFERENCE NUMBERS

1 Semiconductor device
10 Wiring board
11 First semiconductor chip
12 Second semiconductor chip
16 Wire
20 I/O-system electrode pad
21 CA-system electrode pad
22a Bond finger for I/O-system pin, connected to electrode pad of first semiconductor chip
22b Bond finger for I/O-system pin, connected to electrode pad of second semiconductor chip
23 Bond finger for CA-system pin
30 I/O-system connection pad
31 CA-system connection pad
32 Redistribution wiring layer

1. A semiconductor device comprising:
a wiring board
a first semiconductor chip mounted on a main surface of the wiring board; and
a second semiconductor chip stacked on a main surface of the first semiconductor chip, wherein the first semiconductor chip and the second semiconductor chip are each formed in the shape of a plate having a planar shape including a pair of mutually-opposing edges, namely a first edge and a third edge, a second edge perpendicular to the first edge, and a fourth edge opposing the second edge,
wherein the main surface of the first semiconductor chip comprises:
a plurality of first electrodes aligned in such a way as to form a row parallel to the first edge and passing through a central region of the main surface; and
a plurality of second electrodes aligned in the vicinity of the second edge in such a way as to form a row parallel to the second edge, and
wherein the main surface of the second semiconductor chip comprises:
a plurality of third electrodes aligned in such a way as to form a row parallel to the first edge and passing through a central region of the main surface and
a plurality of fourth electrodes aligned in the vicinity of the fourth edge in such a way as to form a row parallel to the fourth edge.

2. The semiconductor device of claim 1, wherein a plurality of first external electrodes and a plurality of second external electrodes are provided on a reverse surface of the wiring board, the first external electrodes are electrically connected to the second electrodes by way of first conduction paths, the second external electrodes are electrically connected to the fourth electrodes by way of second conduction paths, and the lengths of the first conduction paths are substantially equal to the lengths of the second conduction paths.

3. The semiconductor device of claim 1, wherein a plurality of first external electrodes and a plurality of second external electrodes are provided on a reverse surface of the wiring board, and as seen in plan, the plurality of first external electrodes are formed in the vicinity of the second edges of the first semiconductor chip and the second semiconductor chip, in such a way as to form a row parallel to the second edges, and the plurality of second external electrodes are formed in the vicinity of the fourth edges of the first semiconductor chip and the second semiconductor chip, in such a way as to form a row parallel to the fourth edges.

4. The semiconductor device of claim 1, wherein there are provided on the main surface of the wiring board a plurality of first bond fingers aligned so as to form rows respectively in the vicinity of the second edges and in the vicinity of the fourth edges of the first semiconductor chip and the second semiconductor chip, parallel to the second edges, and a plurality of second bond fingers aligned so as to form rows respectively in the vicinity of the first edges and in the vicinity of the third edges of the first semiconductor chip and the second semiconductor chip, parallel to the third edges.

5. The semiconductor device of claim 1, wherein a plurality of fifth electrodes are provided on the main surface of the first semiconductor chip, aligned so as to form a row passing through the central region of the main surface and parallel to the first edge, wherein said fifth electrodes are aligned on an extension of the row formed by the plurality of first electrodes, the plurality of first electrodes are provided toward the end portion of the first semiconductor chip at which the fourth edge is located, the fifth electrodes are provided toward the end portion of the first semiconductor chip at which the second edge is located and are each electrically connected to the second electrodes by way of first redistribution wiring lines formed on the main surface of the first semiconductor chip, and a plurality of sixth electrodes are provided on the main surface of the second semiconductor chip, aligned so as to form a row passing through the central region of the main surface and parallel to the first edge, wherein said sixth electrodes are aligned on an extension of the row formed by the plurality of third electrodes, the plurality of third electrodes are provided toward the end portion of the second semiconductor chip at which the second edge is located, and the sixth electrodes are provided toward the end portion of the second semiconductor chip at which the fourth edge is located and are each electrically connected to the fourth electrodes by way of second redistribution wiring lines formed on the main surface of the second semiconductor chip.

6. The semiconductor device of claim 5, wherein the lengths of the first redistribution wiring lines are substantially equal to the lengths of the second redistribution wiring lines.

7. The semiconductor device of claim 1, wherein the reverse surface of the first semiconductor chip is bonded to the main surface of the wiring board, and the reverse surface of the second semiconductor chip is bonded to the main surface of the first semiconductor chip.

8. The semiconductor device of claim 1, wherein the third electrodes and the fourth electrodes are electrode pads for data input and output.
